(19) United States
(12) Patent Application Publication
(10) Pub. No.: US 2014/0110826 A1
(43) Pub. Date: Apr. 24, 2014

(54) BACKSIDE PROTECTION FOR A WAFER-LEVEL CHIP SCALE PACKAGE (WLCSP)

(71) Applicant: NXP B.V., Eindhoven (NL)

(72) Inventors: Hartmut BUENNING, Norderstedt (DE); Christian Zenz, Graz (AT)

(73) Assignee: NXP B.V., Eindhoven (NL)

(21) Appl. No.: 13/966,506

(22) Filed: Aug. 14, 2013

Related U.S. Application Data
(60) Provisional application No. 61/717,594, filed on Oct. 23, 2012.

(51) Int. Cl. H01L 29/06; H01L 21/78

(52) U.S. Cl. CPC H01L 29/06; H01L 21/78
USPC 257/618; 438/113

(57) ABSTRACT

Consistent with an example embodiment, there is a semiconductor device, having a topside surface and an underside surface, the semiconductor device comprises an active device of an area defined on the topside surface, the topside surface having a first area. A protective material is on to the underside surface of the semiconductor device, the protective material has an area greater than the first area. A laminating film attaches the protective material to the underside surface. The protective material serves to protect the semiconductor device from mechanical damage during handling and assembly onto a product's printed circuit board.

### CROSS-REFERENCE TO RELATED APPLICATION

This application claims the benefit of U.S. Provisional Application No. 61/717,594 filed on Oct. 23, 2012 and is incorporated by reference in its entirety.

### FIELD OF INVENTION

The embodiments of the present invention relate to semiconductor device packaging and, more particularly, to WLCSP packaging having modifications that protect the semiconductor die from handling damage so as to enhance the manufacturability and quality of products.

### BACKGROUND

The electronics industry continues to rely upon advances in semiconductor technology to realize higher-function devices in more compact areas. For many applications realizing higher-functioning devices requires integrating a large number of electronic devices into a single silicon wafer. As the number of electronic devices per given area of the silicon wafer increases, the manufacturing process becomes more difficult.

The packaging of an IC device is increasingly playing a role in its ultimate performance. For example, in mobile devices (i.e., mobile phones, tablet computers, laptop computers, remote controls, etc), WLCSP components are used in their assembly. WLCSP components save valuable space in the mobile device. After assembly, in some example processes, customers encapsulate these WLCSP devices by injection molding or casing. This manual post-processing of the WLCSP may result in device damage. Consequently, the customer may prefer to have the WLCSP product surrounded by non-brittle material, which prevents damage to the die itself, before receiving the product for assembly in to his mobile device.

There is a need for a WLCSP assembly process which can address the challenges raised by the needs of mobile applications.

### SUMMARY

The present disclosure has been found useful in the packaging of semi-conductor devices which find their way into portable electronic devices. In particular, WLCSP products which are furnished as unpackaged die to manufacturers of mobile devices, who in turn encapsulate these devices directly onto a printed circuit board (in an effort to conserve valuable space in the mobile device) may subject these unpackaged die to rough handling. The handling may result in cracking or other latent damage which may not show up until the mobile device reaches the end user.

The user laminates a protective material on the underside of a wafer having device die. Through processing the unpackaged die are protected on their undersides with a oversized protective cover which absorbs the shocks of manual handling during assembly of the mobile device. The process can also be used for chip-scale packaging (CSP) with or without solder balls.

In an example embodiment, there is a method for assembling a wafer level chip scale processed (WLCSP) wafer, the wafer having a topside surface and an underside surface, a plurality of device die on the topside surface. The method comprises back grinding, to a first thickness, the underside surface the wafer. Mounted onto a first sheet of dicing foil is the underside of the wafer; the wafer is sawed to a depth of the first thickness. The dicing foil is stretched and space is made between each one of the plurality device die. The plurality of spaced device die is remounted on the topside surface onto a second sheet of dicing foil. A layer of protection material of a second thickness is laminated onto the undersides of the plurality of spaced device die. To a depth of the second thickness, there is a sawing through the protection material between each of the plurality of spaced device die. Each of the plurality of spaced device die has a protective layer on the underside, the protective layer has an area greater than the area of each one of the plurality of device die.

In another embodiment, there is a semiconductor device, having a topside surface and an underside surface. The semiconductor device comprises, an active device of an area defined on the topside surface, the topside surface having a first area. A protective material is on to the underside surface of the semiconductor device, the protective material has an area greater than first area. A laminating film attaches the protective material to the underside surface.

The above summaries of the present disclosure are not intended to represent each disclosed embodiment, or every aspect, of the present invention. Other aspects and example embodiments are provided in the figures and the detailed description that follow.

### BRIEF DESCRIPTION OF THE DRAWINGS

The invention may be more completely understood in consideration of the following detailed description of various embodiments of the invention in connection with the accompanying drawings, in which:

FIG. 1 is a flow diagram of an embodiment according to the disclosure;

FIG. 2 depicts an embodiment according to the present disclosure as it protects the WLCSP device;

FIGS. 3A-3H illustrate the assembly of an example WLCSP device according an embodiment according to the disclosure;

FIG. 4A illustrates a finished device assembled with plastic foil according to an embodiment of the present disclosure; and

FIG. 4B illustrates a finished device assembled with a metal foil according to an embodiment of the present disclosure.

While the invention is amenable to various modifications and alternative forms, specifics thereof have been shown by way of example in the drawings and will be described in detail. It should be understood, however, that the intention is not to limit the invention to the particular embodiments described. On the contrary, the intention is to cover all modifications, equivalents, and alternatives falling within the spirit and scope of the invention as defined by the appended claims.

### DETAILED DESCRIPTION

The disclosed embodiments have been found useful in preventing damage to the Wafer Level Chip-Scale Product (WLCSP) devices during their assembly. The process provides mechanical protection to the silicon device by mounting the device onto a protective material larger than the device die dimensions; the protective material forms a boundary on the device underside that keeps assembly tooling from directly contacting the silicon device, thus avoiding chipping and other damage. Such a process may be integrated into the customary back-end assembly.

In an example embodiment, the user takes a wafer substrate having devices. The wafer undergoes electrical tests (e.g., E-sort) to sort out non-functioning devices; other processes may forego E-sort and cull out non-functioning devices after packaging. The user laminates the WLCSP wafer of a thickness onto a grinding foil. The backside of the WLSCP wafer is ground down to a thinner thickness. The thinned WLCSP wafer is mounted dicing foil and the grinding foil is removed. The WLSCP wafer is diced. The dicing foil is stretched to separate the device die. The device die are mounted on their contact side onto another film surface. Backsides of device die are laminated with a foil of either metal or plastic. After backside lamination, the protected device die are separated.

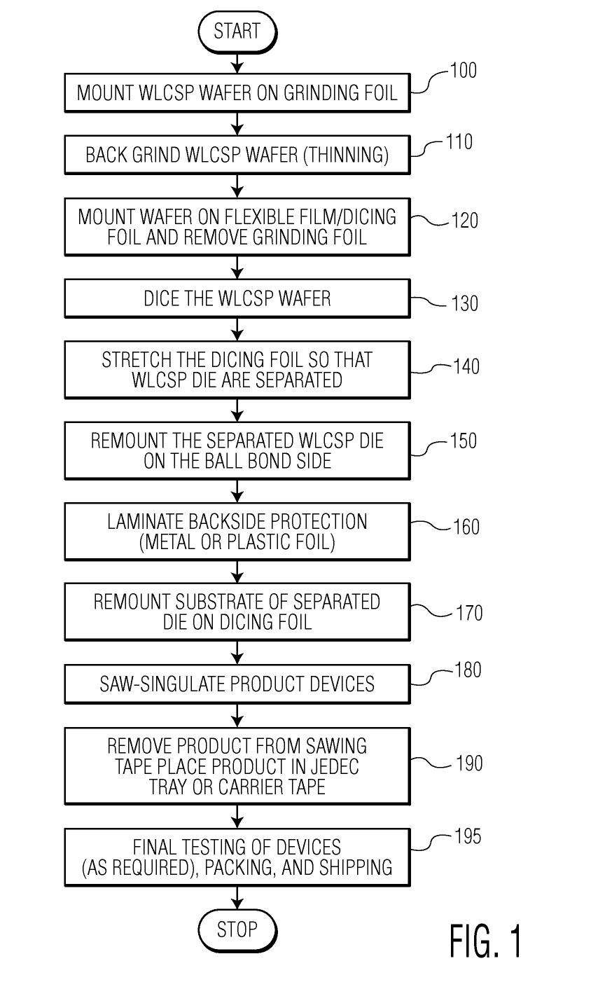

Refer to FIG. 1. In an example embodiment according to the present disclosure, a wafer having undergone electrical testing is mounted on a grinding foil 100. Back grinding of the wafer underside thins out the wafer 110. The wafer is mounted on a flexible film/dicing foil; the grinding foil is removed 120. The WLCSP wafer is diced (e.g, sawed) to define the individual WLCSP devices 130. The dicing foil is stretched so that the WLCSP device die are separated 140. The separated device die are remounted, on the ball bond side, onto another mounting foil 150. Upon the backside of the separated device die, lamination is applied 160.

The stretched wafer with separated device die is remounted onto a second dicing foil 170. The device die are sawn apart (e.g., “singulated”). The singulated product is removed from the sawing tape; product is placed into appropriated tray (i.e., JEDEC approved, etc.) 190 or may be spooled onto carrier tape for tape and reel packaging applications. Depending upon device type, devices undergo and optional final electrical testing, packing, and shipping to end user 195.

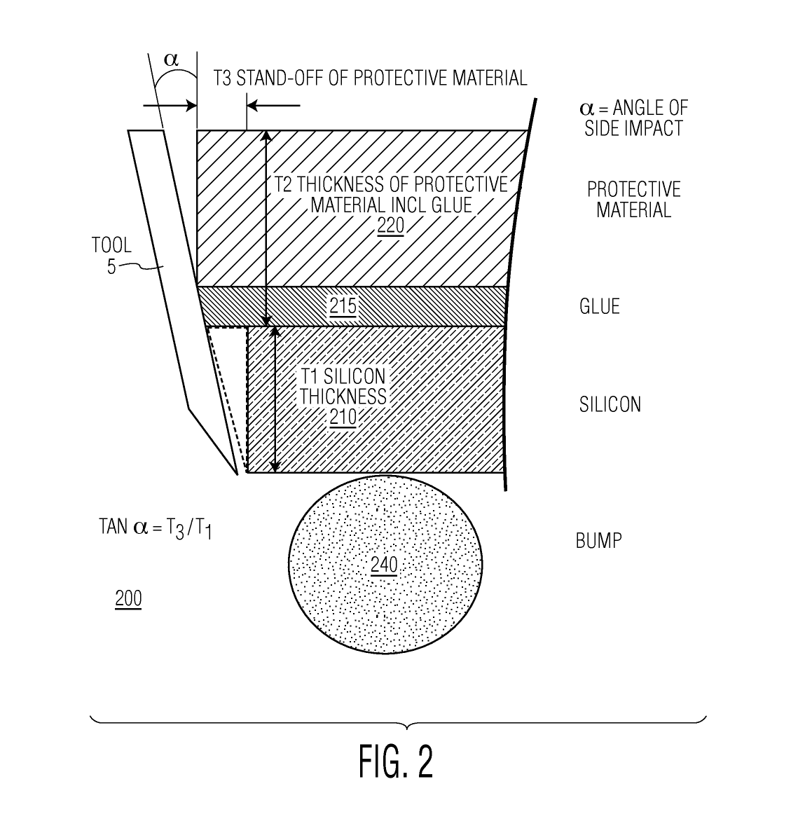

Refer to FIG. 2. In an example embodiment, an assembly 200 includes an silicon device 210 of a thickness T₁. A protection angle α and the silicon thickness T₁ define the stand-off distance T₃ of the protection material. For example, to protect a device die of thickness, T₁=150 μm, against an impact by a tool 5 with a 20 degree impact angle, a stand-off of about 55 μm is appropriate. Generalized, the stand-off distance is:

T₃=tan αT₁ (1)

The total thickness, T₂ of the protective material 220 and glue 215 is determined by materials used. The amount of standoff would be achieved by the stretching of the dicing foil 140 to separate out the WLCSP die a prescribed amount, remounting the separated WLCSP die on the contact pad side 150, then laminating the backside protection thereon 160. For example, a pre-grinding thickness, T₀ of an eight-inch wafer (20.3 2cm) is about 725 μm, for a six-inch wafer (15.24 cm). Note that this technique may be applied to wafer substrates of any size and may be useful for twelve-inch (30.48 cm) substrates. Further, devices using balls, bumps, pads, etc. benefit from the protective material. In an example process, a WLCSP is ground to a thickness of about 400 μm with a ball bond side of about 200 μm. It is desirable to achieve a minimum wafer thickness, T₁; however, it is limited by the technical ability to thin down wafers with 200 μm bumps. Thickness, T₁ in an example process may be in the range of about 150 μm to about 250 μm.

The protective material 220 laminated with a glue 215, to the underside of the silicon 210 may be plastic of metal. The plastic material may be made of, but not necessarily limited to, KAPTON®, PTFE (polytetrafluoroethylene), molding compound, etc. KAPTON is the brand name of the polyimide film (i.e., poly-oxydiphenylene-pyromellitimide) manufactured by the E.I. du Pont de Nemours and Company. The protective material 220 and glue 215 used for the lamination must withstand a temperature range of about 200° C. to 300° C. usually encountered in the reflow process for WLCSP device assembly. Metal protective material 220 may be of, but not necessarily limited to, stainless steel, copper, and copper alloys; these metals are similar to those used in the manufacturing of lead frames.

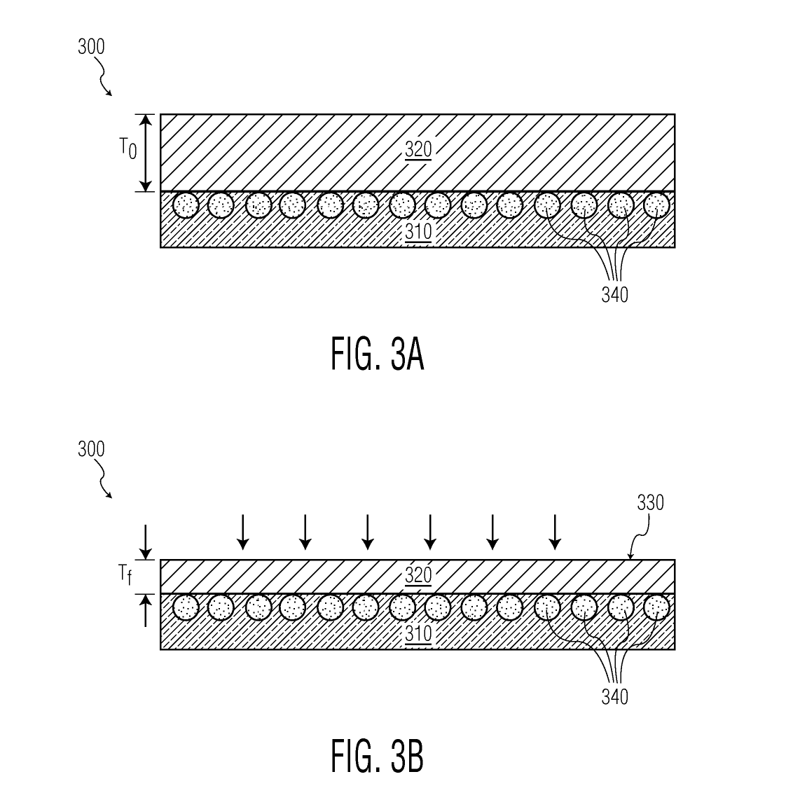

Refer to FIGS. 3A-3H. In an example WLCSP wafer 200 with active devices 320, ball bonds 340 connect to the active regions of devices, FIG. 3A. In this example, each potential device will have four ball bonds. The WLCSP wafer 320 is mounted on the ball bond side to a grinding foil 310. Referring to FIGS. 3B-3E, the backside 330 is ground down to a defined thickness (from an initial wafer thickness T₀ to a final wafer thickness T_{f}). The thinned wafer 300 is mounted on a flexible film/dicing foil 335 on its backside 330. Apparatus 360 (e.g., a tooling jig in the manufacturing equipment) keeps the flexible film 335 and attached thinned wafer 300 in tension (FIG. 3C). Referring to FIG. 3D, the thinned wafer 300 is sliced with a wafer saw 10 or equivalent, resulting in separate devices 325 with ball bonds 345. In the apparatus 360, the flexible film 335 is stretched separating device die 325 farther apart. Refer to FIGS. 3E-3H. After stretching, the flexible film 335 the device die 325 are remounted onto another film 355 on the ball bond 345 side which is in another apparatus 362. With a glue 370, backside protection 365 is applied to the undersides 330 of the remounted device die 325.

Refer to FIG. 3G. Upon the backside protection 365, the device die are remounted onto a sawing tape 375, the sawing tape 375 mounted on apparatus 363. Refer to FIG. 3H. Wafer saw 15 clears the space between device die 325 and cuts through the backside protection film 365 so that the now-protected devices 325 may be separated into single devices.

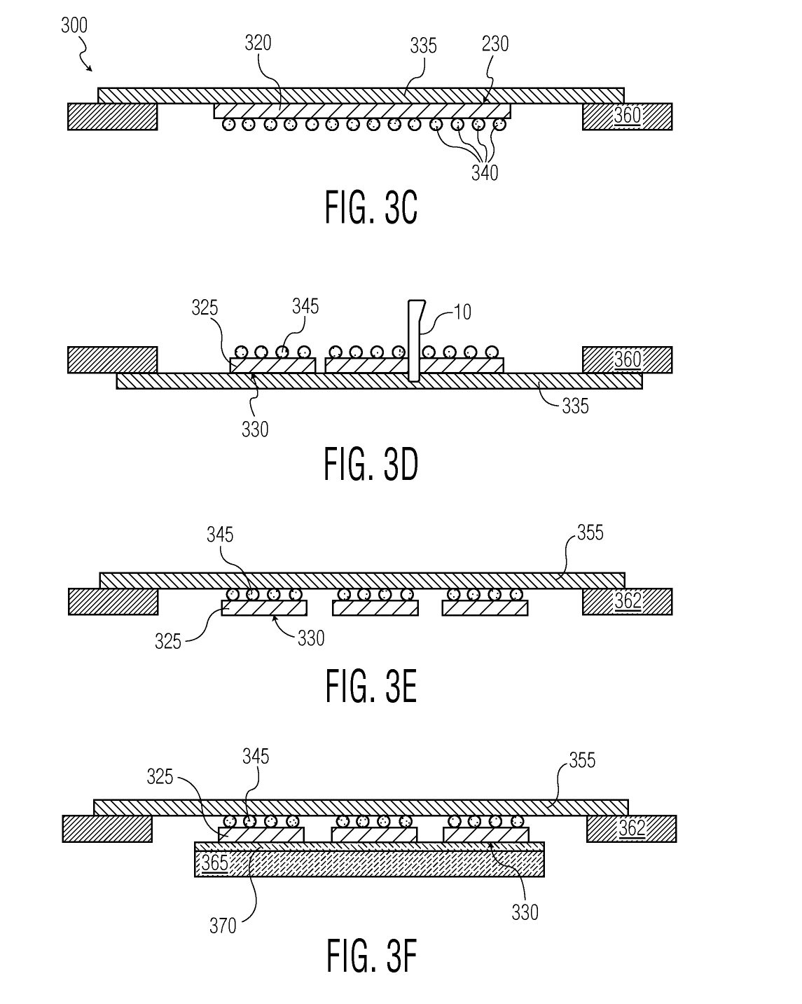

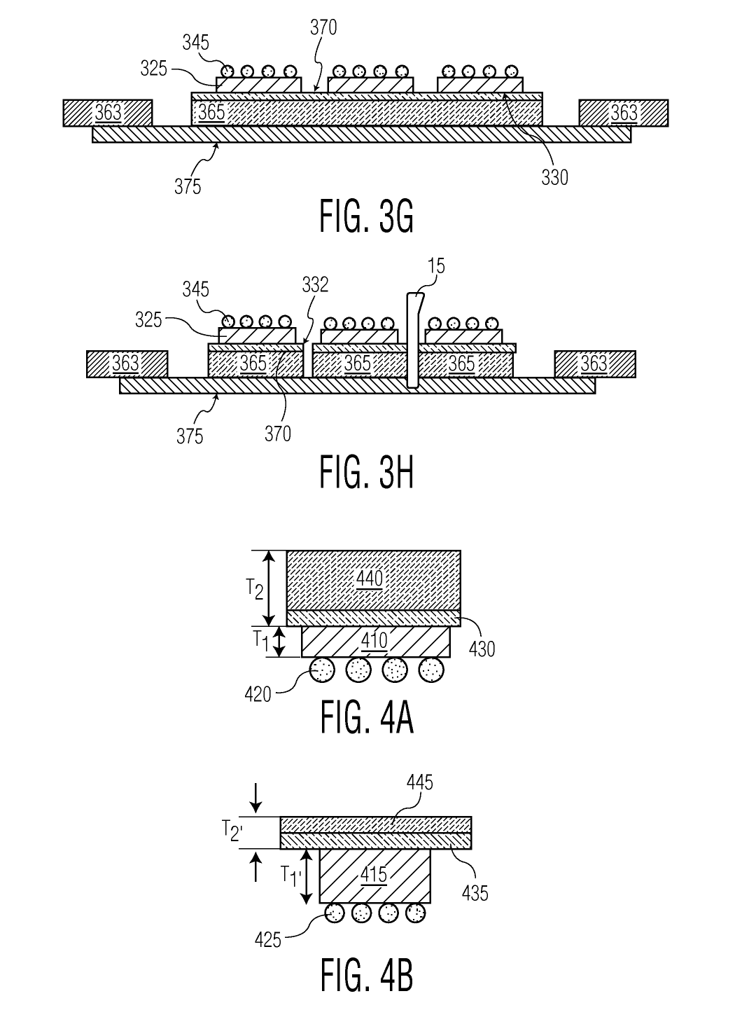

Refer to FIG. 4A. In an example embodiment, on device die 410, having ball bonds 420, the backside protection 440 may be a polymer, plastic material combined with the glue layer 430. The device 410 has been back-ground to a thickness T₁. The protective backside protection 440 and glue layer 430 would be at a thickness T₂. The total allowable thickness for the device die's application is the sum of T₁ and T₂.

Refer to FIG. 4B. In another example embodiment, on device die 415, having ball bonds 425, backside protection 445 may be metallic material. Metals may include copper or steel, but are not necessarily limited to those. The device 415 is back-ground to a thickness T₁′. The protective backside protection 445 and glue layer 435 would be at a thickness T₂′. Also, the metal protective backside protection 445 would likely be thinner than the plastic backside protection 440. As with FIG. 2, the total allowable thickness for the device die's application is the sum of T₁′ and T₂′. It is possible in a particular application using two or more device die, to have one product die protected with a polymer material and another product die protected with a metallic material; the overall thickness of each product may be the same, however, so as to accommodate a fixed height within the system application.

The embodiments discussed, protect both the underside and sidewall of the WLCSP device against mechanical impacts from subsequent handling during assembly (i.e., tweezers, pipettes, vacuum wands, etc.). The thickness of the material and the T₃ standoff distance determine the degree of protection.

In the example embodiment of a plastic/coating, the coating should be as thick as possible to minimize the effective silicon thickness and by the degree of exposure (to sources of mechanical damage) of the side wall area of the sensitive silicon. A relative small stand-off distance T₃ should be enough to securely protect the chip itself against mechanical impacts.

Numerous other embodiments of the invention will be apparent to persons skilled in the art without departing from the spirit and scope of the invention as defined in the appended claims.

1. A method for assembling a wafer level chip scale processed (WLCSP) wafer, the wafer having a topside surface and an underside surface, a plurality of device die on the topside surface, the method comprising:
back grinding, to a first thickness, the underside surface the wafer;
mounting the underside of wafer onto a first sheet of dicing foil;
sawing the wafer to a depth of the first thickness;
stretching the dicing foil and making a space between each one of the plurality device die;
remounting the plurality of spaced device die on the topside surface onto a second sheet of dicing foil;
laminating a layer of protection material of a second thickness onto the underside of the plurality of spaced device die;
sawing through the protection material between each of the plurality of spaced device die to a depth of the second thickness ,
wherein each of the plurality of spaced device die has a protective layer on the underside, the protective layer having an area greater than the area of each one of the plurality of device die.

2. The method as recited in claim 1, wherein the protection material is at least one of the following: metal, plastic.

3. The method as recited in claim 2, wherein the first thickness of the wafer and the second thickness of the protection material is determined by the type of protection material used.

4. The method as recited in claim 2,
wherein the plastic is selected from at least one of the following: poly-oxydiphenylene-pyromellitimide, polytetrafluoroethylene, molding compound; and
wherein the metal is selected from at least one of the following: copper, stainless steel, copper alloy.

5. A semiconductor device, having a topside surface and an underside surface, the semiconductor device of a thickness, comprising:
an active device of an area defined on the topside surface, the topside surface having a first area;
a protective material on to the underside surface of the semiconductor device, the protective material having an area greater than first area; and
a laminating film of the same area of that of the protective material, attaching the protective material to the underside surface;
wherein a stand-off distance of the combination of the protective material and of laminating film is a function of the semiconductor device thickness and the tangent of an angle of tooling impact upon a vertical side surface the semiconductor device.

6. The semiconductor device as recited in claim 5, wherein the protective material is at least one of the following: metal, plastic.

7. The semiconductor device as recited in claim 5, wherein the laminating film is at least one of the following: glue.
